(19) United States
(12) Patent Application Publication
(10) Pub. No.: US 2009/0057677 A1
(43) Pub. Date: Mar. 5, 2009

(54) FERROELECTRIC DEVICE AND METHOD FOR FABRICATING THE SAME

(76) Inventors: Kazunori ISOGAI, Kyoto (JP); Akihiro KAMADA, Toyama (JP)

Correspondence Address: MCDERMOTT WILL & EMERY LLP, 600 13TH STREET, NW, WASHINGTON, DC, 20005-3096, US

(21) Appl. No.: 12/193,238

(22) Filed: Aug. 18, 2008

(30) Foreign Application Priority Data
Aug. 27, 2007 (JP) 2007-219413

(51) Int. Cl. H01L 29/04; H01L 21/28

(52) U.S. Cl. 257/64; 438/3; 257/E29.004; 257/E21.208

(57) ABSTRACT

A method for fabricating a ferroelectric device includes Step S1 of forming a polycrystalline electrode on or above a substrate in which a MOS transistor is formed, Step S2 of performing metal organic chemical vapor deposition to form an amorphous film of bismuth titanate on the polycrystalline electrode, and Step S3 of performing annealing at a temperature in a predetermined range to make the amorphous film be a polycrystalline ferroelectric film made up of a large number of bismuth titanate having a layered perovskite structure. Step S3 includes a sub-step of increasing a temperature of the amorphous film to a lower limit of the predetermined temperature range at a temperature increase rate at which crystal nuclei are not grown.

### BACKGROUND OF THE INVENTION

The present invention relates to a ferroelectric device and a method for fabricating the ferroelectric device, and particularly relates to a ferroelectric device using a ferroelectric film formed of a layered perovskite material and a method for the fabricating the ferroelectric device.

A ferroelectric memory (FeRAM) is a non-volatile memory utilizing spontaneous polarization of a ferroelectric film, and is characterized in that information can be rewritten (or the direction of polarization can be changed) thereon at high speed with low voltage. As described above, FeRAMs exhibit characteristics that flash memories do not have, but there are still problems in increasing the capacity of FeRAMs. That is because a memory cell in a known FeRAM is formed of a MOS transistor and a ferroelectric capacitor with a planar structure, and the capacitor is formed to have a larger area for the purpose of maintaining a large amount of electric charges. Therefore, to realize a large capacity FeRAM, a planar area which the capacitor occupies has to be reduced.

Considering that the memory performance of a ferroelectric capacitor is determined by a product of density of spontaneous polarization charges generated by a ferroelectric film (which will be hereafter referred to “charge density”) and a surface area of the capacitor, in order to maintain the memory performance, a sufficiently large surface area of the capacitor has to be ensured, even when the planner area is reduced, by forming the capacitor into not a planar structure but a concave or convex three-dimensional structure or the charge density has to be improved.

The density of charges generated by the ferroelectric film varies depending on a crystal plane of the ferroelectric material. For example, in a ferroelectric material made of bismuth titanate, which is one of layered perovskite materials, assuming that the charge density of the (100) plane is 100, the charge densities of the (001) plane, the (117) plane, the (110) plane and the (104) plane are 8, 55, 71 and 83, respectively. Therefore, to improve the charge density, it is important to perform orientation control for a crystal plane of a ferroelectric material which is vertically oriented to an electric field applied to a ferroelectric film (or in parallel to an electrode interface).

For example, in “New Development of Ferroelectric Memory, CMC Publishing Co., Ltd. pp. 17-25”, a single crystalline ferroelectric film of bismuth titanate having a (104) plane oriented as a parallel plane to a substrate surface is formed on a single crystalline electrode of ruthenium titanate having a (111) plane oriented as a parallel plane to the substrate surface, at a substrate temperature of 850° C., using metal organic chemical vapor deposition (MOCVD) for forming a ferroelectric film in a three dimensional structure.

Moreover, for example, in Japanese Laid-Open Publication No. 2000-169297, crystalline nuclei having a plane orientation of (117) are grown on a polycrystalline electrode of platinum having a (111) plane oriented as a parallel plane to a substrate surface, at a substrate temperature of 550° C., using MOCVD and subsequently an additional film is formed at a substrate temperature of 450° C., thereby forming a polycrystalline ferroelectric film having a (117) plane substantially oriented as a parallel surface to the substrate surface.

Since a lattice constant of ruthenium titanate and a lattice constant of platinum are substantially the same, it can be understood from the above-described techniques that a (117) plane is lattice matched with a (111) plane of such material at a substrate temperature of 550° C. and a (104) plane is lattice matched with the (111) plane at a substrate temperature of 850° C.

However, according to a method for fabricating a ferroelectric device, disclosed in “New Development of Ferroelectric Memory, CMC Publishing Co., Ltd. pp. 17-25”, the substrate temperature is high, i.e., 850° C., and thus, when the size of MOS transistors constituting a memory cell is small, a defective operation due to increase in contact resistance and the like is caused.

Moreover, according to a method for fabricating a ferroelectric device, disclosed in Japanese Laid-Open Publication No. 2000-169297, the substrate temperature is low, i.e., 450° C. to 550° C., but it is only possible to control crystal plane orientation of a ferroelectric material so that a (117) plane or a (001) plane each having a smaller charge density than that of a (104) plane is oriented as a parallel surface to the substrate surface.

### SUMMARY OF THE INVENTION

In the above-described points, the present invention has been devised to provide a ferroelectric device including a polycrystalline ferroelectric film made of bismuth titanate in which a (104) plane with a large charge density is oriented substantially in parallel to an electrode interface and a method for fabricating the ferroelectric device.

A ferroelectric device according to one embodiment of the present invention includes: a MOS transistor formed in a substrate; a polycrystalline electrode formed on or above the substrate; and a polycrystalline ferroelectric film formed on the polycrystalline electrode, the polycrystalline ferroelectric film being made up of a large number of bismuth titanate crystals having a layered perovskite structure. In the ferroelectric device, a (104) plane in the bismuth titanate crystals is oriented substantially in parallel to an interface of the polycrystalline electrode and the polycrystalline ferroelectric film.

According to one embodiment of the present invention, it is preferable that the ferroelectric device further includes an insulation film formed on or above the substrate so as to have a concave portion, and the polycrystalline electrode is formed so as to cover inner walls of the concave portion.

According to one embodiment of the present invention, in the ferroelectric device, the bismuth titanate crystals occupy 70% or more of an area of the polycrystalline ferroelectric film, and the (104) plane in the bismuth titanate crystals is tilted from the interface by an angle in the range from −15° or more to +15° or less.

According to one embodiment of the present invention, in the ferroelectric device, the polycrystalline electrode is formed of platinum or strontium ruthenium oxide, and a (111) plane in the polycrystalline electrode is oriented substantially in parallel to the interface.

According to one embodiment of the present invention, the ferroelectric device is characterized in that the polycrystalline ferroelectric film contains a rare earth element.

A method for fabricating a ferroelectric device according to one embodiment of the present invention includes the steps of: a) forming a polycrystalline electrode on or above a substrate in which a MOS transistor is formed; b) performing metal organic chemical vapor deposition to form an amorphous film of bismuth titanate on the polycrystalline electrode; and c) performing annealing at a temperature in a predetermined range to make the amorphous film be a polycrystalline ferroelectric film made up of a large number of bismuth titanate having a layered perovskite structure, the step c) includes a sub-step of increasing a temperature of the amorphous film to a lower limit of the predetermined temperature range at a temperature increase rate at which crystal nuclei are not grown, and a (104) plane in the bismuth titanate crystals is oriented substantially in parallel to an interface of the polycrystalline electrode and the polycrystalline ferroelectric film.

According to the ferroelectric device fabrication method of one embodiment of the present invention, a heat quantity applied to a MOS transistor is small and the polycrystalline ferroelectric film of bismuth titanate is formed so as to have a (104) plane oriented substantially in parallel to an interface with the electrode. Therefore, a fine ferroelectric device can be achieved.

It is preferable that the ferroelectric device fabrication method of one embodiment of the present invention further includes, before the step a), a step d) of forming on or above the substrate an insulation film having a concave portion, and in the step a), the polycrystalline electrode is formed so as to cover inner walls of the concave portion.

Thus, a finer ferroelectric device can be realized.

In the ferroelectric device fabrication method of one embodiment of the present invention, it is preferable that the temperature increase rate is 10° C./sec or more on an average, and the predetermined temperature range is 680° C. or more and 780° C. or less.

The reason why the above-described temperature increase rate and temperature range are preferable is that when the temperature increase rate is lower than 10° C./sec on an average and it takes a long time to increase the temperature of the amorphous film to a lower limit of the predetermined temperature range, or when crystallization is performed by annealing at a lower temperature than the predetermined temperature range, crystals having some other plane orientation than a (104) plane orientation are generated in parallel to the interface.

In the ferroelectric device fabrication method of one embodiment of the present invention, it is preferable that in the step b), a bismuth composition in the amorphous film is 3.8 or more and 4.1 or less where a titanium composition is standardized with 3.

The reason why the bismuth composition is set to be in the above-described range is that if the bismuth composition in the amorphous film is smaller than 3.8, pyrochlore structure crystals with no spontaneous polarization are increased and, if the bismuth composition is larger than 4.1, layered perovskite structure crystals with a small spontaneous polarization, having a plane orientation of (001) are increased, so that the charge density is reduced.

In the ferroelectric device fabrication method of one embodiment of the present invention, it is preferable that in the step b), the amorphous film contains a rare earth element, and a composition of a sum of bismuth and the rare earth element in the amorphous film is 3.8 or more and 4.1 or less where a titanium composition is standardized with 3.

Thus, a plane orientation of crystals is hardly influenced, so that performances such as a leakage current and the like can be improved.

In the ferroelectric device fabrication method of one embodiment of the present invention, the step a) includes a sub-step of performing sputtering or metal organic chemical vapor deposition to form the polycrystalline electrode of platinum or strontium ruthenium oxide.

Thus, in the predetermine temperature range, a (111) plane lattice matched with a (104) plane in bismuth titanate having a layered perovskite structure is oriented substantially in parallel to the interface of the polycrystalline electrode and the polycrystalline ferroelectric film.

According to the ferroelectric device formation method of one embodiment of the present invention, a heat quantity applied to a MOS transistor is small and the polycrystalline ferroelectric film of bismuth titanate is formed so as to have a (104) plane with a relatively large charge density, oriented substantially in parallel to an interface with the electrode. Therefore, a fine ferroelectric device can be achieved.

### BRIEF DESCRIPTION OF THE DRAWINGS

FIG. 1 is a cross-sectional view illustrating an exemplary structure of major part of a ferroelectric device according to an embodiment of the present invention.

FIG. 2 is a flow chart showing a method for fabricating a ferroelectric device according to the embodiment of the present invention.

FIGS. 3A through 3D are graphs showing the dependency of crystal plane distribution on bismuth composition for polycrystalline ferroelectric films according to the embodiment of the present invention.

FIG. 4 is a cross-sectional view illustrating an exemplary structure of major part of a ferroelectric device according to a modified example of the embodiment of the present invention.

### DESCRIPTION OF THE PREFERRED EMBODIMENTS

Hereafter, embodiments of the present invention will be described with reference to the accompanying drawings.

A ferroelectric device according to an embodiment of the present invention will be hereafter described.

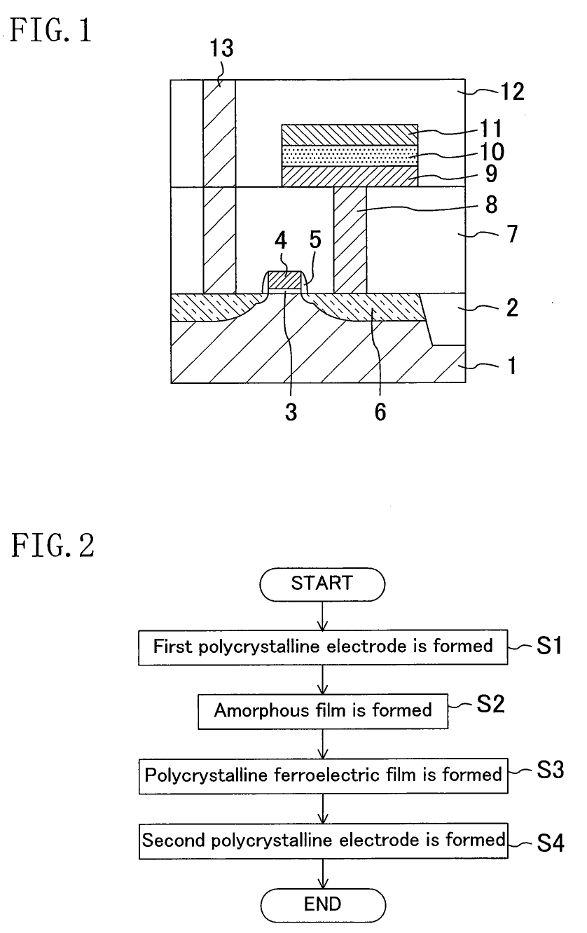

FIG. 1 is a cross-sectional view illustrating an exemplary structure of major part of the ferroelectric device of the embodiment of the present invention.

As shown in FIG. 1, an isolation (STI: shallow trench isolation) 2 for dividing a device formation region is formed in a semiconductor substrate 1 of, for example, a silicon oxide film. On part of the semiconductor substrate 1 located in the device formation region, a gate insulation film 3 and a gate electrode 4 are formed of, for example, silicon and polysilicon, respectively, in this order. On side surfaces of the gate insulation film 3 and the gate electrode 4, sidewalls 5 are formed of, for example, a silicon nitride film. An impurity doped layer 6 for functioning as source/drain regions is formed in parts of a surface layer portion of the semiconductor substrate 1 located at both sides of the gate electrode 4 and the sidewalls 5.

An interlevel insulation film 7 is formed of, for example, a silicon oxide film (BPSG film) to which B, P or the like is added on the semiconductor substrate 1 so as to cover the gate electrode 4 and the sidewalls 5. In the interlevel insulation film 7, a contact plug 8 is formed of, for example, tungsten or polysilicon so as to pass through the interlevel insulation film 7 and have a bottom end reach the impurity doped layer 6.

Moreover, a first polycrystalline electrode 9 is formed of, for example, platinum on the interlevel insulation film 7 so as to have a lower surface connected to an upper end of the contact plug 8. On the first polycrystalline electrode 9, a polycrystalline ferroelectric film 10 is formed of, for example, a large number of bismuth titanate crystals. A second polycrystalline electrode 11 is formed of, for example, platinum on the polycrystalline ferroelectric film 10.

In this embodiment, the first polycrystalline electrode 9 and the second polycrystalline electrode 11 are formed so that a (111) plane of each of the first polycrystalline electrode 9 and the second polycrystalline electrode 11 is oriented substantially in parallel to a principal surface of the semiconductor substrate 1. The (104) planes of a large number of bismuth titanate crystals, which occupy 70% or more of an area of the polycrystalline ferroelectric film, are tilted from an interface of the polycrystalline ferroelectric film 10 with the first polycrystalline electrode 9 (or the second polycrystalline electrode 11) by an angle in the range from −15° to +15°.

On the interlevel insulation film 7, an interlevel insulation film 12 is formed of, for example, a silicon oxide film so as to cover the first polycrystalline electrode 9, the polycrystalline ferroelectric film 10 and the second polycrystalline electrode 11. A contact plug 13 is formed of, for example, tungsten or polysilicon in the interlevel insulation film 12 and the interlevel insulation film 7 so as to pass through the interlevel insulation film 12 and the interlevel insulation film 7 and have a lower end reach the impurity doped layer 6.

In FIG. 1, the structure in which a MOS transistor is formed in the semiconductor substrate 1 and the polycrystalline ferroelectric film 10 sandwiched between the polycrystalline electrodes 9 and 11 is provided on the semiconductor substrate 1 with the interlevel insulation film 7 interposed therebetween is illustrated as an example. However, a structure in which the polycrystalline ferroelectric film 10 sandwiched between the polycrystalline electrodes 9 and 11 is directly formed on the semiconductor substrate 1 may be adopted.

A method for fabricating a ferroelectric device according to one embodiment of the present invention will be hereafter described.

In this case, a method for fabricating a first polycrystalline electrode 9, a polycrystalline ferroelectric film 10 and a second polycrystalline electrode 11 which are features of this embodiment will be described. Other parts can be fabricated by a known method and therefore the description thereof will be omitted.

FIG. 2 is a flow chart showing a method for fabricating a ferroelectric device of the embodiment of the present invention.

In Step S1, using sputtering or metal organic chemical vapor deposition, a first polycrystalline electrode 9 is formed of, for example, platinum on an insulation film 7 formed of a silicon oxide film. By forming the first polycrystalline electrode 9 in this manner, the first polycrystalline electrode 9 can be formed to have a (111) plane oriented substantially in parallel to a principal surface of the semiconductor substrate 1.

Next, in Step S2, using metal organic chemical vapor deposition, an amorphous film is formed of bismuth titanate on the first polycrystalline electrode 9.

According to results of examinations conducted by the present inventors, the following was found. Since a temperature necessary to decompose bismuth and titanium materials described in Japanese Laid-Open Publication No. 2000-169297 is high, a film can not be properly formed when a substrate temperature is set to be low. On the other hand, when a substrate temperature is set to be high, crystallization begins and an amorphous film of bismuth titanate is difficult to obtain.

To cope with this, according to this embodiment, Bi(MMP)₃/ECH and Ti(MMP)₃/ECH (both available from ADEKA corporation), each of which has a low decomposition temperature were used as bismuth and titanium materials, respectively. Bi(MMP)₃/ECH was obtained by dissolving Bi(MMP)₃ (i.e., trimethoxy dimethyl dipropoxy bismuth) in an ECH (ethyl cyclohexane) solution at a concentration of 0.2 mol/L. Ti(MMP)₃/ECH was obtained by dissolving Ti(MMP)₃ (trimethoxy dimethyl dipropoxy titanium) in an ECH solution at a 0.1 mol/L. With use of these materials, for example, an amorphous film formed of bismuth titanate could be obtained by introducing Bi(MMP)₃/ECH at a flow rate of 0.110 sccm, Ti(MMP)₃/ECH at a flow rate of 0.490 sccm, ECH simple substance at a flow rate of 0.290 sccm, and oxygen at a flow rate of 1800 sccm, into a chamber under the condition where a substrate temperature was 400° C. and a chamber pressure was 4.0-5.0 Torr (note that 1 Torr is about 1.33×10² Pa (this applies to the following description as well)). As a result of evaluation using fluorescence X ray spectrometer (SMAT 2250 available from Technos Co., Ltd.), as for the film composition of the obtained amorphous film, it was found that a bismuth composition was about 4.0 where a titanium composition was standardized with 3. The amorphous film was grown to a thickness of about 45 nm for a film forming time of about 20 min.

Next, in Step S3, annealing is performed in a certain temperature range to make the amorphous film obtained in Step S2 be a polycrystalline ferroelectric film 10 made up of a large number of bismuth titanate crystals each having a layered perovskite structure. In an actual example, the temperature of the film was increased to 750° C. in an oxygen atmosphere at an increase rate of 10° C./sec on an average and a pressure of 760 Torr, and then the film was kept at 750° C. for 1 minute. Thereafter, the film was cooled down.

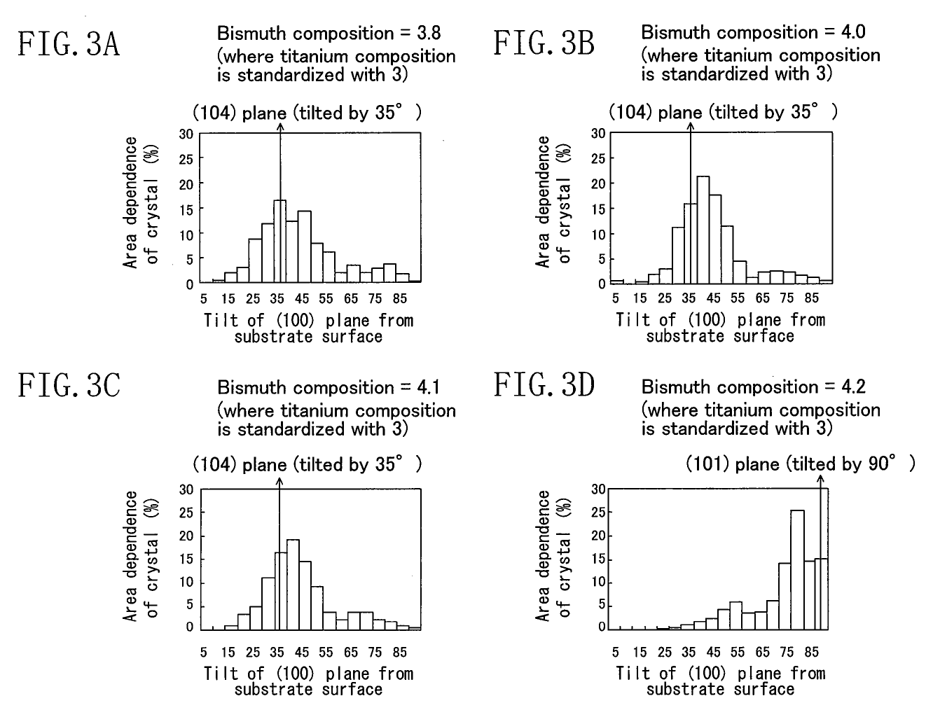

FIG. 3B is a graph showing results of evaluation of plane orientation for a plurality of bismuth titanate crystals constituting a polycrystalline ferroelectric film obtained in Step S3 using an EBSP (Electron Back Scattering Pattern) method. Note that a state where a (100) plane is oriented in parallel to the principal surface of the semiconductor substrate 1 is indicated by 0° and a state where a (001) plane is oriented in parallel to the principal surface of the semiconductor substrate 1 is indicated by 90°. Note also that when the (100) plane is tilted from the principal surface of the semiconductor substrate 1 by about 35°, a (104) plane is oriented in parallel to the principal surface of the semiconductor substrate.

As shown in FIG. 3B, the plurality of bismuth titanate crystals occupying 70% of the area of the polycrystalline ferroelectric film 10 were distributed with being tilted in the range from −15° to +15° from an angle of about 35° from the principal surface of the semiconductor substrate 1.

FIGS. 3A and 3C show results of evaluation performed in the same manner as in FIG. 3B to a polycrystalline ferroelectric film obtained with the flow rate ratio between Bi(MMP)₃/ECH and Ti(MMP)₃/ECH adjusted using the EBSP method. As shown in FIGS. 3A and 3C, even when the flow rate ratio was adjusted so that a bismuth composition was 3.8 and 4.1 with respect to a titanium composition of 3, a similar crystal plane distribution to that of FIG. 3B was obtained. FIGS. 3A through 3C show results for the polycrystalline ferroelectric films obtained by performing annealing at 750°. But when annealing was performed at a temperature in a range from 680° or more to 780° or less, a similar crystal plane distribution was obtained. Moreover, when the flow rate ratio was adjusted in the same manner to obtain a smaller bismuth composition than 3.8, pyrochlore crystals (stoichiometric ratio between titanium and bismuth=2:2, capable of existing as crystal with a smaller bismuth composition than that of the layered perovskite crystal) were increased. On the other hand, as shown in FIG. 3D, when the bismuth composition was set to be 4.2 or more, the amount of crystals tilted by 90°, i.e., (001) plane crystals was increased. Accordingly, a value of 2 Pr, which will be described later, was reduced.

Next, in Step 4, a second polycrystalline electrode 11 is formed of, for example, platinum on the polycrystalline ferroelectric film 10 using sputtering or metal organic chemical vapor deposition. Thus, the second polycrystalline electrode 11 is formed so as to have a (111) plane oriented substantially in parallel to the principal surface of the semiconductor substrate 1. Thereafter, if there are damages in a surface of the polycrystalline ferroelectric film 10 in forming the second polycrystalline electrode 11, recovery annealing may be performed at 700° C. for about 1 minute.

The hysteresis characteristic of the ferroelectric device obtained in the above-described manner was evaluated at 1.5 V. As a result of the evaluation, a large charge density of 2 Pr=16.3 μC/cm² was obtained.

According to the ferroelectric device fabrication method of this embodiment, a heat quantity applied to a MOS transistor is small and the polycrystalline ferroelectric film 10 is formed of a plurality of bismuth titanate crystals so as to have a (104) plane with a large charge density oriented substantially in parallel to an interface with each electrode (each of the first polycrystalline electrode 9 and the second polycrystalline electrode 11). Therefore, a fine ferroelectric device can be achieved.

According to this embodiment, in the annealing, the temperature increase rate at which a temperature of an amorphous film is increased to 750° C. is 10° C./sec on an average. Examination was also conducted for cases where annealing was performed under the condition where the temperature increase rate was changed and other conditions were the same as described above. Specifically, the temperature of the film was increased to 750° C. in an oxygen atmosphere at a temperature increase rate of 2° C./sec on an average and a pressure of 760 Torr and, thereafter, the film was maintained at 750° C. for 1 minute and then cooled down. Thus, bismuth titanate crystals, occupying about 70% of the area of the polycrystalline ferroelectric film 10, were formed so as to have a (110) plane tilted from the principal surface of the semiconductor substrate 1 by −15° or more and +15° or less.

From the above described examination, it can be understood that as for bismuth titanate crystals constituting the polycrystalline ferroelectric film 10, different crystal planes are grown depending on the temperature increase rate. Then, if the polycrystalline ferroelectric film 10 is formed at 450° according to this embodiment, crystal nuclei having a plane orientation of (111) are formed in parallel to the principal surface of the semiconductor substrate 1. If the polycrystalline ferroelectric film 10 is formed at 400° C., an amorphous film is formed and, if the polycrystalline ferroelectric film 10 is formed at 550° C. according to Japanese Laid-Open Publication No. 2000-169297, crystal nuclei having a plane orientation of (117) are generated. Based on this, assuming that crystal nuclei having a plane orientation of (111) are generated at a temperature in a range from about 420° C. to 520° C., if the temperature of the amorphous film is increased at a temperature increase rate of 2° C./sec on an average, the temperature stays in the temperature range for 50 seconds. This implies that a sufficient number of crystal nuclei are formed in 50 seconds, and in a subsequent step of increasing the temperature of the film to 750° C., a sufficient number of crystal nuclei are grown before crystal nuclei having a plane orientation of (104). Therefore, as in this embodiment, by increasing the temperature of the amorphous film at a temperature increase rate of 10° C./sec on an average, a time in which the temperature of the film stays in the above-described temperature range is only 10 seconds and thus crystal nuclei having a plane orientation of (110) are not generated but crystals having a plane orientation of (104) are generated with higher priority. As the discussion above indicates, in annealing of this embodiment, the temperature increase rate at which the temperature of the amorphous film is increased to 750° C. is preferably 10° C./sec. Specifically, the temperature increase rate until the temperature of the amorphous film reaches a lower limit of the above-described temperature range from 680° C. or more to 780° C. or less is preferably 10° C./sec on an average at which crystal nuclei having a plane orientation of (111) or (117) are not grown.

According to this embodiment, bismuth titanate is used as a material of the polycrystalline ferroelectric film 10. However, bismuth titanate containing a rare earth element such as lanthanum may be used as a material for the polycrystalline ferroelectric film 10. Thus, device performances such as a leakage current and the like can be improved with giving almost no influence on the plane orientation of crystals. When bismuth titanate containing a rare earth element is used, for the above-described reason, it is preferable that the composition ratio of the sum of bismuth and a rare earth element is 3.8 or more and 4.1 or less where the titanium composition is standardized with 3.

According to this embodiment, platinum is used as a material of the first and second polycrystalline electrodes 9 and 11. However, strontium ruthenium oxide may be used as a material of the first and second polycrystalline electrodes 9 and 11. Thus, strontium ruthenium oxide has substantially the same lattice constant as that of platinum and the first and second polycrystalline electrodes 9 and 11 can be easily formed to have a (111) plane, as a plane having the highest atomic density, oriented in parallel to an electrode interface.

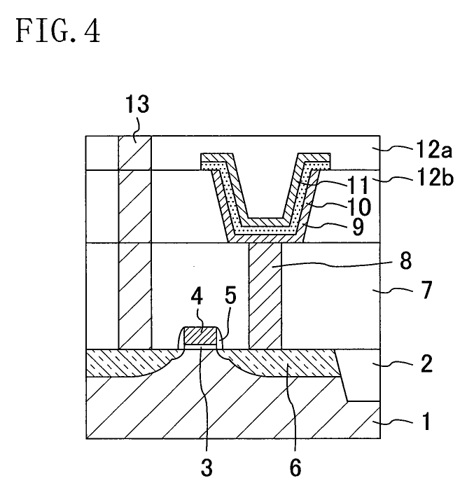

According to this embodiment, as shown in FIG. 1, the case where a capacitor formed of the first polycrystalline electrode 9, the polycrystalline ferroelectric film 10 and the second polycrystalline electrode 11 has a planer structure has been described. However, as shown in FIG. 4, even when the capacitor is a three-dimensional capacitor in a three-dimensional structure, the same effects as those described above can be achieved. Specifically, a structure in which a three-dimensional capacitor including a first polycrystalline electrode 9, a polycrystalline ferroelectric film 10 and a second polycrystalline electrode 11 is formed so as to cover inner walls of a concave part formed in an interlevel insulation film 12b and then an interlevel insulation film 12a is formed so as to cover the three-dimensional capacitor may be adopted.

According to this embodiment, the case where the amorphous film formed of bismuth titanate is crystallized and then the second polycrystalline electrode 11 is formed has been described. However, a method in which the second polycrystalline electrode 11 is formed on the amorphous film formed of bismuth titanate and then the amorphous film is crystallized may be adopted. Thus, not only the same crystal plane distribution can be obtained as one obtained by the above-mentioned embodiment but also surface roughness in the polycrystalline ferroelectric film 10 due to annealing can be suppressed.

According to this embodiment, the case where the substrate temperature at which an amorphous film of bismuth titanate is formed is 400° C. has been described. However, as long as an amorphous film of bismuth titanate is obtained, the substrate temperature is not limited to 400° C.

According to this embodiment, the case where the chamber pressure at which an amorphous film of bismuth titanate is formed is 4.5 Torr has been described. However, as long as an amorphous film of bismuth titanate is obtained, the chamber pressure is not limited to 4.5 Torr.

A ferroelectric device according to the present invention and a method for fabricating the ferroelectric device are useful to FeRAMs.

What is claimed is:

1. A ferroelectric device comprising:
a MOS transistor formed in a substrate;
a polycrystalline electrode formed on or above the substrate; and
a polycrystalline ferroelectric film formed on the polycrystalline electrode, the polycrystalline ferroelectric film being made up of a large number of bismuth titanate crystals having a layered perovskite structure,
wherein a (104) plane in the bismuth titanate crystals is oriented substantially in parallel to an interface of the polycrystalline electrode and the polycrystalline ferroelectric film.

2. The ferroelectric device of claim 1, further comprising an insulation film formed on or above the substrate so as to have a concave portion,
wherein the polycrystalline electrode is formed so as to cover inner walls of the concave portion.

3. The ferroelectric device of claim 1, wherein the bismuth titanate crystals occupy 70% or more of an area of the polycrystalline ferroelectric film, and
the (104) plane in the bismuth titanate crystals is tilted from the interface by an angle in the range from −15° or more to +15° or less.

4. The ferroelectric device of claim 1, wherein the polycrystalline electrode is formed of platinum or strontium ruthenium oxide, and
a (111) plane in the polycrystalline electrode is oriented substantially in parallel to the interface.

5. The ferroelectric device of claim 1, wherein the polycrystalline ferroelectric film contains a rare earth element.

6. A method for fabricating a ferroelectric device, the method comprising the steps of:
a) forming a polycrystalline electrode on or above a substrate in which a MOS transistor is formed;
b) performing metal organic chemical vapor deposition to form an amorphous film of bismuth titanate on the polycrystalline electrode; and
c) performing annealing at a temperature in a predetermined range to make the amorphous film be a polycrystalline ferroelectric film made up of a large number of bismuth titanate having a layered perovskite structure,
wherein the step c) includes a sub-step of increasing a temperature of the amorphous film to a lower limit of the predetermined temperature range at a temperature increase rate at which crystal nuclei are not grown, and
a (104) plane in the bismuth titanate crystals is oriented substantially in parallel to an interface of the polycrystalline electrode and the polycrystalline ferroelectric film.

7. The method of claim 6, further comprising, before the step a), a step d) forming on or above the substrate an insulation film having a concave portion,
wherein in the step a), the polycrystalline electrode is formed so as to cover inner walls of the concave portion.

8. The method of claim 6, wherein in the step c),
the temperature increase rate is 10° C./sec or more on an average, and
the predetermined temperature range is 680° C. or more and 780° C. or less.

9. The method of claim 6, wherein in the step b),
a bismuth composition in the amorphous film is 3.8 or more and 4.1 or less where a titanium composition is standardized with 3.

10. The method of claim 6, wherein in the step b),
the amorphous film contains a rare earth element, and
a composition of a sum of bismuth and the rare earth element in the amorphous film is 3.8 or more and 4.1 or less where a titanium composition is standardized with 3.

11. The method of claim 6, wherein the step a) includes a sub-step of performing sputtering or metal organic chemical vapor deposition to form the polycrystalline electrode of platinum or strontium ruthenium oxide.
